(19) United States
(12) Patent Application Publication
(10) Pub. No.: US 2013/0286762 A1
(43) Pub. Date: Oct. 31, 2013

(54) MEMORY CONTROL APPARATUS AND METHOD

(71) Applicant: Foundation of Soongsil University-Industry Cooperation, (US)

(72) Inventor: Chan-Ho LEE, Seoul (KR)

(73) Assignee: Foundation of Soongsil University-Industry Cooperation, Seoul (KR)

(21) Appl. No.: 13/735,171

(22) Filed: Jan. 7, 2013

(30) Foreign Application Priority Data
Apr. 26, 2012 (KR) 10-2012-0043727

(51) Int. Cl. G11C 8/12

(52) U.S. Cl. CPC G11C 8/12
USPC 365/230.03

(57) ABSTRACT

Provided are a memory control apparatus and a memory control method. In the memory control apparatus and memory control method, data are distributively stored in a plurality of banks in sequence, and the corresponding data are written to or read from the memory, based on row address information obtained by exchanging a portion of row information and bank information with each other. According to the invention, if a new row begins when the host or the processor accesses the memory, a host or a processor accesses another bank, and thus the block data can be read or written without a waiting cycle. In addition, the memory control apparatus and the memory control method can be implemented with low complexity available through simple address conversion in the memory control apparatus.

### PRIORITY

This application claims priority to and the benefit of Korean Patent Application No. 2012-0043727, filed on Apr. 26, 2012, the disclosure of which is incorporated herein by reference in its entirety.

### BACKGROUND OF THE INVENTION

1. Field of the Invention

The present invention relates to a memory control apparatus and a memory control method, and more particularly to an apparatus and a method in which data are distributively stored in a plurality of banks in sequence, and the corresponding data are written to or read from the memory, based on row address information obtained by exchanging portions of row information and bank information with each other.

2. Description of the Related Art

In signal processing in which a moving image and a still image are processed, an image is generally processed in units of frames, and pixel data in the form of a rectangle with a two dimensional array is required for image signal processing. Here, the number of pixels included in one frame depends on the resolution of the image. For example, a standard definition (SD) image has a pixel array size of 720×480, and a high definition (HD) image has a pixel array size of 1920×1080. Generally, to easily calculate an address when reading and writing image data, image pixel data are stored in the memory in the same format as a frame. In this case, an external DRAM is commonly used as the memory. The DRAM generates waiting cycles when data in a new row are read.

The size of a block of pixel data necessary for image processing depends on the application. The size usually has various sizes of a small size of 2×2 to a large size of 128×128. Of course, the block of pixel data may have the form of not only a square but also a rectangle. To read block data, data stored in the multiple continuous rows should be read. During this process, since operations of opening and closing a new row should be performed multiple times, there is a problem in that the number of waiting cycles increases.

One of the solutions to solve such a problem is a method of reading desired block data in advance, storing the read data in a buffer memory, and then providing the data immediately when necessary. However, this method has a problem in that the size of the buffer memory is increased in proportion to the size of the block data. Another way to solve the problem is to continuously store pixel data of each block in a row by changing the storing order of data. However, this method has problems in that it leads to complicated address calculation and, in the case of a high-resolution image, the image data are stored in two or more rows, in which case generation of the waiting cycles is inevitable and a method of calculating the address need to be changed whenever the sizes of a frame and a block of the image are varied.

### SUMMARY OF THE INVENTION

A technical object of the present invention is to provide a memory control apparatus and a memory control method wherein data are distributively stored in a plurality of banks in sequence, and the corresponding data are written to or read from the memory, based on row address information obtained by exchanging portions of row information and bank information with each other.

Another technical object of the present invention is to provide a non-transitory computer-readable recording medium that records a program for allowing a computer to execute a memory control method wherein data are distributively stored in a plurality of banks in sequence, and the corresponding data are written to or read from the memory, based on row address information obtained by exchanging portions of row information and bank information with each other.

A memory control apparatus to achieve technical object described above according to the present invention is a memory control apparatus for controlling a memory which includes a plurality of banks. The memory control apparatus includes; a system interface unit configured to receive a memory access request including original row address information which includes bank information and row information; an address conversion unit configured to obtain converted row address information by exchanging the bank information and portions of the row information with each other in the original row address information; a memory interface unit configured to distributively write data to the plurality of banks in sequence, or read data from the plurality of banks; and a memory control unit configured to distributively store data in the memory through the memory interface unit in sequence, or read data from the memory through the memory interface unit, using the converted row address information obtained by the address conversion unit according to the memory access request received through the system interface unit.

A memory control method to achieve the technical object described above according to the present invention is a memory control method of a memory control apparatus for controlling a memory which includes a plurality of banks. The memory control method includes: receiving a memory access request including original row address information which includes bank information and row information; obtaining converted row address information by exchanging portions of the row information and the bank information with each other in the original row address information; and distributively writing data to the plurality of banks in sequence, or reading data from the plurality of banks, using the converted row address information according to the received memory access request.

To achieve the technical objects, a non-transitory computer-readable medium according to the present invention records a program for allowing a computer to execute any one of the methods described above.

According to the memory control apparatus and the memory control method of the present invention, data are distributively stored in a plurality of banks in sequence, and the corresponding data are written to or read from the memory based on row address information obtained by exchanging portions of row information and bank information with each other. Thereby, a host or a processor accesses another bank if a new row begins when the host or the processor accesses the memory, and thus the block data can be read or written without a waiting cycle.

Also, the address can be generated by assuming that the data are going to be stored in the same bank continuously, and thus a host or a processor can operate irrespective of detailed operations according to the present invention, and operation performance can be improved. Accordingly, a host or a processor which accesses a memory can use a method of storing data in the same bank in an existing way.

In addition, the present invention can be implemented with low complexity available through simple address conversion in the memory control apparatus.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a block diagram illustrating a memory control apparatus according to a preferred embodiment of the present invention.

FIG. 2 is a block diagram illustrating in detail a configuration of a memory control apparatus according to the preferred embodiment of the present invention.

FIG. 3 is a diagram illustrating a distributive storing operation of image data according to the preferred embodiment of the present invention.

FIG. 4 is a flowchart illustrating a memory control method according to the preferred embodiment of the present invention.

### DETAILED DESCRIPTION OF EXEMPLARY EMBODIMENTS

Exemplary embodiments of the present invention will be described in detail below with reference to the accompanying drawings. While the present invention is shown and described in connection with exemplary embodiments thereof, it will be apparent to those skilled in the art that various modifications can be made without departing from the spirit and scope of the invention.

Hereinafter, a memory control apparatus and a memory control method according to the present invention will be described in detail with reference to the accompanying drawings.

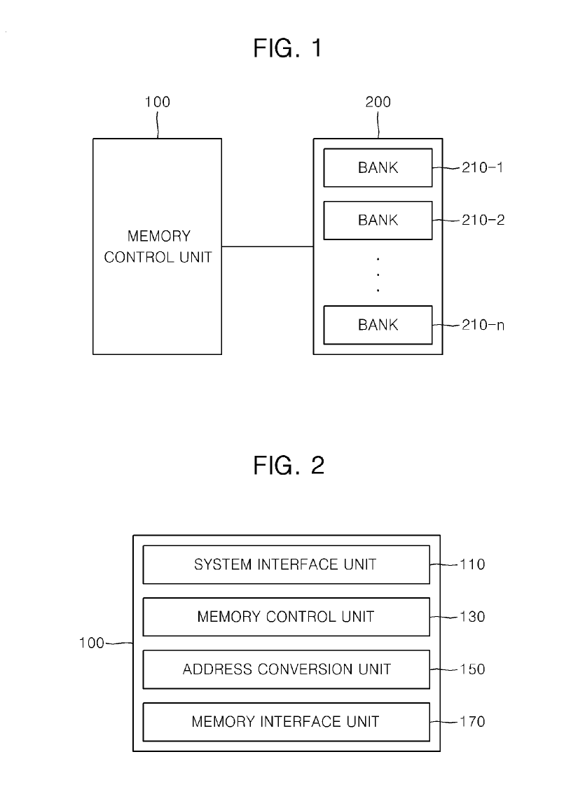

FIG. 1 is a block diagram illustrating a memory control apparatus according to a preferred embodiment of the present invention.

Referring to FIG. 1, a memory control apparatus 100 is connected to a memory 200 equipped with a plurality of banks 210-1 to 210-n. Here, the memory 200 includes a dynamic random access memory (DRAM) or the like. Also, the number of banks included in the memory 200 is 2^{m} (n=2^{m}), where m is a natural number.

The memory control apparatus 100 distributively stores data which are provided from an external device according to a request from the external device (not shown) such as a host and a processor in the plurality of banks 210-1 to 210-n in sequence. In addition, the memory control apparatus 100 reads data from the memory 200 and provides the corresponding data to the external devices according to the request from the external devices.

FIG. 2 is a block diagram illustrating in detail a configuration of a memory control apparatus according to the preferred embodiment of the present invention.

Referring to FIG. 2, the memory control apparatus 100 includes a system interface unit 110, a memory control unit 130, an address conversion unit 150, and a memory interface unit 170.

The system interface unit 110 receives a memory access request from the external devices. Here, when the memory access request is a data read request, the memory access request includes data address information. Alternatively, when the memory access request is a data write request, the memory access request includes the data address information and the corresponding data. Here, the data address information includes row address information and column address information. The row address information includes bank information and row information. Hereinafter, the row address information included in the data address information of the memory access request received from the external device will be called original row address information.

The memory control unit 130 generates command and address information for controlling the memory 200 according to the memory access requests received from the external devices through the system interface unit 110. In this case, the memory control unit 130 distributively stores the corresponding data in the memory 200 through the memory information unit 170 in sequence or reads the corresponding data from the memory 200 through the memory interface unit 170, using converted row address information generated by the address conversion unit 150 based on the original row address information.

The memory interface unit 170 distributively writes the data to the plurality of banks 210-1 to 210-n in sequence, or reads the data from the plurality of banks 210-1 to 210-n according to the control of the memory control unit 130. For example, when the data are image data with a format of a two-dimensional array, the memory interface unit 170 distributively stores the image data in the plurality of banks 210-1 to 210-n in units of rows according to the control of the memory control unit 130. That is, neighboring rows are stored in separate banks.

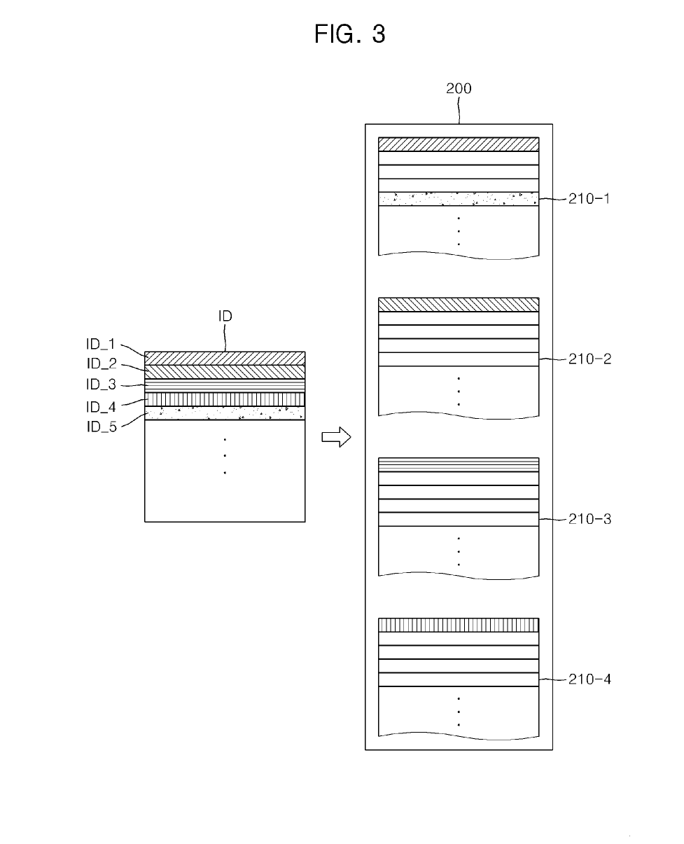

FIG. 3 is a diagram illustrating a distributive storing operation of image data according to the preferred embodiment of the present invention.

As shown in FIG. 3, the memory interface unit 170 can distributively store image data ID with the format of a two-dimensional array in four banks 210-1 to 210-4 so that neighboring rows are stored in different banks. The first row ID_1 of the image data ID is stored in the first row of the first bank 210-1, the second row ID_2 of the image data ID is stored in the first row of the second bank 210-2, the third row ID_3 of the image data ID is stored in the first row of the third bank 210-3, the fourth row ID_4 of the image data ID is stored in the first row of the fourth bank 210-4, and the fifth row ID_5 of the image data ID is stored in the fifth row of the first bank 210-1 again.

The address conversion unit 150 obtains the converted row address information by exchanging bank information and a portion of row information with each other in the original row address information received from the external device through the system interface unit 110. In other words, the address conversion unit 150 obtains the converted row address information by exchanging the first m bits and the last m bits with each other in the original row address information. For example, when the memory 200 is equipped with 4 (2²) banks, the address conversion unit 150 can obtain the converted row address information by exchanging the first 2 bits and the last 2 bits with each other in the original row address information as shown in the following [Table 1].

TABLE 1

| | | | |
|---|---|---|---|
| Original | Storage | Converted | Storage |
| row address | location | row address | location |

| information | Bank | Row | information | Bank | Row |
|---|---|---|---|---|---|
| 00...000 | 0 | 0 | 00...000 | 0 | 0 |
| 00...001 | 0 | 1 | 00...000 | 1 | 0 |
| 00...010 | 0 | 2 | 00...000 | 2 | 0 |
| 00...011 | 0 | 3 | 00...000 | 3 | 0 |
| 00...100 | 0 | 4 | 00...000 | 0 | 4 |
| 01...000 | 1 | 0 | 00...000 | 0 | 1 |
| 10...000 | 2 | 0 | 00...000 | 0 | 2 |
| 11...000 | 3 | 0 | 00...000 | 0 | 3 |
| 11...001 | 3 | 1 | 00...000 | 1 | 3 |

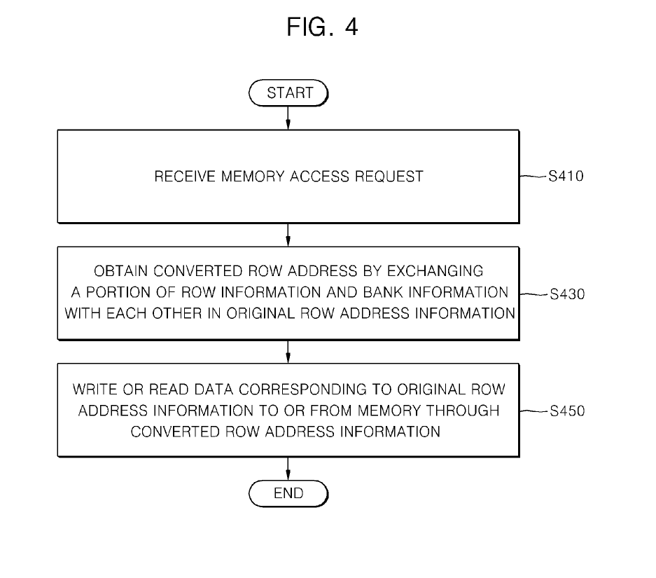

FIG. 4 is a flow chart illustrating a memory control method according to the preferred embodiment of the present invention.

The memory control apparatus 100 receives the memory access request (S410). Then, the memory control apparatus 100 obtains the converted row address information by exchanging the bank information and a portion of the row information with each other in the original row address information (S430). In other words, the memory control apparatus 100 obtains the converted row address information by exchanging the first m bits and the last m bits with each other in the original row address information.

Next, the memory control apparatus 100 distributively stores the data corresponding to the original row address information through the converted row address information in the memory 200 in sequence, or reads the corresponding data from the memory 200 through the converted row address information (S450). Then, the memory control apparatus 100 provides the result of access to the memory to the external device.

Here, under the assumption that data are continuously stored in the same bank, the external device generates an address. Therefore, to support the memory access operation according to the present invention, no additional change of software or hardware is required. Accordingly, by simply modifying the existing memory control apparatus, the memory access operation according to the present invention can be used with no other changes in the system.

To measure the improvement degree of performance of the present invention, the number of cycles necessary for read and write is compared to the number of cycles in the existing method. The data block used when the performance measurement is performed is the image data with sizes of 9×9, 16×16 and 5×5. Here, a pixel is represented as 8 bits in the image data with the sizes of 9×9 and 16×16, and a pixel is represented as 32 bits in the image data with the size of 5×5. The result of the comparison between the present invention and the existing method is shown in the following [Table 2].

TABLE 2

| Number of cycles | |
|---|---|
| Writing | Reading |

| | | | | |
|---|---|---|---|---|
| | Existing | The present | Existing | The present |
| Block size | method | invention | method | invention |

SDR SDRAM

| | | | | |
|---|---|---|---|---|
| 9 × 9 | 68 | 36 | 71 | 39 |
| 16 × 16 | 140 | 65 | 128 | 68 |
| 5 × 5 | 46 | 30 | 49 | 33 |

DDR2 SDRAM

| | | | | |
|---|---|---|---|---|
| 9 × 9 | 147 | 69 | 99 | 53 |
| 16 × 16 | 147 | 69 | 99 | 53 |
| 5 × 5 | 89 | 50 | 57 | 42 |

As can be confirmed from the above [Table 2], in the case of SDR SDRAM, it is found that the performance of the present invention is improved by about 33 to 54% compared to the performance of the existing method, and in the case of DDR2 SDRAM, the performance of the present invention is improved by about 26 to 53% compared to the performance of the existing method.

However, the memory control apparatus and the memory control method according to the present invention should be able to use a network protocol capable of performing communication of an outstanding address type such as an advance extensible interface (AXI). Accordingly, when a new row is expected to begin, the information on the next memory access request can be predicted in advance to open the next bank.

In other words, in the existing method, after reading all the data of one row, the waiting time for 4 cycles to 6 cycles to perform a PRECHARGE command and an ACTIVE command for accessing the next row is necessary. However, in the memory control apparatus and the memory control method according to the present invention, when the next row is in the different bank, the PRECHARGE command or the ACTIVE command of the corresponding row can be sent in advance for a NOP command cycle between the data and the command for reading or writing. Therefore, reading or writing can be performed with no waiting time or a significantly reduced waiting cycle.

Of course, the memory control apparatus and the memory control method according to the present invention can also use a network protocol such as an advanced high-performance bus (AHB). In this case, the present invention is equipped with a master interface and a slave interface; receives an access request through the slave interface, and transmits data through the master interface. Therefore, the external device that requests data should be equipped with the slave interface.

The present invention can also be implemented as computer-readable code on a computer-readable recording medium. The computer-readable recording medium includes all types of recording devices storing computer-readable data. Examples of computer-readable recording media include a ROM, a RAM, a CD-ROM, a magnetic tape, a floppy disk, and an optical data storage device, and may also be implemented in the form of carrier waves (transmission through the Internet). In addition, the computer-readable recording medium may be distributed in computer devices connected to wired and wireless networks, and the computer-readable code may be stored and operated in a distributive manner.

So far, although preferred example embodiments have been described in detail, the present invention shall not be limited to these example embodiments; the scope of this invention instead shall be determined from the scope of the following claims including their equivalents.

1. A memory control apparatus for controlling a memory including a plurality of banks, the memory control apparatus comprising:
a system interface unit configured to receive a memory access request including original row address information which includes bank information and row information;
an address conversion unit configured to obtain converted row address information by exchanging the bank information and a portion of the row information with each other in the original row address information;
a memory interface unit configured to distributively write data to the plurality of banks in sequence, or read data from the plurality of banks; and
a memory control unit configured to distributively store data in the memory through the memory interface unit in sequence, or read data from the memory through the memory interface unit, using the converted row address information obtained by the address conversion unit according to the memory access request received through the system interface unit.

2. The memory control apparatus according to claim 1, wherein the memory includes 2^{m} banks, and the image data with the format of two dimensional array are distributively stored in the 2^{m} memory of banks in units of rows in the memory, and
the address conversion unit obtains the converted row address information by exchanging the first m bits and the last m bits with each other in the original row address information.

3. A memory control method of a memory control apparatus for controlling a memory including a plurality of banks, the memory control method comprising:
receiving a memory access request including original row address information which includes bank information and row information;
obtaining converted row address information by exchanging a portion of the row information and the bank information with each other in the original row address information; and
distributively writing data to the plurality of banks in sequence, or reading the data from the plurality of banks, using the converted row address information according to the received memory access request.

4. The memory control method according to claim 3, wherein the memory includes 2^{m} banks, and the image data with the format of a two-dimensional array are distributively stored in the 2^{m} memory of banks in units of rows in the memory, and
the memory control method includes obtaining the converted row address information by exchanging the first m bits and the last m bits with each other in the original row address information in the obtaining converted row address information.

5. A non-transitory computer-readable recording medium that records a program for causing a computer to execute the memory control method described in claim 3.

6. A non-transitory computer-readable recording medium that records a program for causing a computer to execute the memory control method described in claim 4.
